(19) United States
(12) Patent Application Publication
(10) Pub. No.: US 2015/0325249 A1
(43) Pub. Date: Nov. 12, 2015

(54) Reverse Hearing Aid [RHA]

(71) Applicant: Marlena Nunn Russell, Chattanooga, TN (US)

(72) Inventor: Marlena Nunn Russell, Chattanooga, TN (US)

(21) Appl. No.: 14/323,895

(22) Filed: Jul. 3, 2014

Related U.S. Application Data
(60) Provisional application No. 61/858,875, filed on Jul. 26, 2013.

(51) Int. Cl. G10L 21/02; H03G 3/20; H04R 1/14

(52) U.S. Cl. CPC G10L 21/02; H04R 1/14; H03G 3/20

(57) ABSTRACT

Method and apparatus for speech aid for use in treating speech impaired individuals utilizing a Throat Microphone paired with a wireless communications device, with or without Bluetooth pairing capability; or a portable device, which will capture low energy sound waves from speech impaired individuals, transmitted wirelessly to be reproduced from a speaker, and stored for future use through a recording device and utilizing speech to text.

### FIELD OF THE INVENTION

This invention relates generally to an improved throat microphone and the use of wireless communications technology devices and Bluetooth technology being utilized as electronic speech aid, for any person challenged with a voice disorder, having difficulty projecting their voice at a high enough energy level for comprehension.

### BACKGROUND OF THE INVENTION

It is well documented that contact microphones or throat microphones, adapted to engage the throat or other vibrating body portion adjacent to the larynx of a wearer are well known. The primary focus of use tends to be on people who need to talk in a high noise or wind situation, such as construction workers, or paintball and airsoft teams, more importantly, security staff that needs to communicate quietly without alerting everyone around them.

In addition, the existing products for electronic speech aid have a primary focus on speed rate of individuals diagnosed with Parkinson's Disease. U.S. Pat. No. 8,275,624, June 2012, Shelia Wright, and U.S. Pat. No. 4,289,938, September 2012, U.S. Pat. No. 8,275,604, Kehoe.

It is interesting that neither of these devices focus on speech aid. While they address specific populations or audiences, they do not address the millions of people challenged with a voice disorder, having difficulty projecting their voice at a high enough energy level for comprehension.

Further, none of the existing products utilize the throat microphone or any microphones with wireless communications devices such as cell phone, IPhone, IPad, etc., as a speech aid; nor do they apply Bluetooth technology capabilities for speech aid. The throat microphone U.S. Pat. No. 4,607,383, was patented in August 1986; before the 1994 introduction of Bluetooth, so the option to pair the Bluetooth technology throat microphone and the wireless phone did not exist during the initial patenting.

U.S. Pat. D441353 May 1, 2001 Sun, Yung-Nein patented a new design but that design did not include Bluetooth, nor was it utilized as a speech aid device. Many products exist that provide speech aid to the impaired user but are offered in several different product purchases, not in one application, like the Reverse Hearing Aid.

My invention and new method and apparatus comes too late for my father who passed away in 2008, and now my dear friend Regina who passed away in the spring of 2013.

My father was diagnosed with lung cancer. During his last days, his ability to speak at a volume that would allow others i.e., family members, caregivers, Physicians or medical staff to hear him became impossible. He became very frustrated and humiliated when asking his medical staff for simple requests such as “water”, or an escort to the “bathroom” that they simply could not understand. In addition, he was too weak to write his request on tablets.

My dear friend Regina was on her dying bed and she too was so weak that she could barely speak above a whisper. Her family and friends would literally rest their ear against her mouth to try to understand her requests and we never did. Regina was so frail and weak, she would lift her finger and point to something and move her lips but we never knew what she was pointing at, or what she was asking. She passed away without our ever knowing what her request was. The last words of a dying loved one are usually muttered very low as the vocal cords are very weak.

It would be nice to have a device that is affordable, portable, and which utilizes current Bluetooth technology, along with wireless communications devices, to overcome one or more of the disadvantages that millions of speech impaired people are faced with daily.

### SUMMARY OF THE INVENTION

The present method and invention improvement meets this need by providing a solution with a new method and apparatus for use of a portable and wearable device, such as the throat microphone, which cancels out all outside noise through sensors that only pick up the skin vibration signals from the vocal cord when the user is talking, even if the user is speaking at a whisper.

Additionally, this new method and apparatus incorporates the use of the throat microphone with wireless communications technology, i.e., cell phone, IPhone, IPad, etc., and Bluetooth.

Statists show that there are more than 6 billion people with mobile phone subscriptions. Utilizing wireless communications as a tool for speech aid, allows any person with a comparable wireless communications device the ability to utilize that device as a speech aid if there is a need.

Utilizing my improved method and apparatus with the improved throat microphone, with or without the Bluetooth technology option, allows the user the option of communications through IPhone, IPad etc. The user can elect to convert speech to text through voice messaging.

In addition, The new method allows the user to attach the Bluetooth compatible [or not] throat microphone to a 2 way radio. The 2 way radio device is comprised of a built in microphone, transmitter, receiver, storage unit, signal processor, and speaker. The throat microphone is attached because it does not require the user to project his/her voice through the air, and it converts the energy from the sound waves produced by the individual to an electric signal.

There are currently products in the market that provide speech aid to impaired users, which offer additional choices or features such as voice amplification, or portability, or recording and playback or wireless transmission at additional costs.

Other devices, target a specific population of people. U.S. Pat. No. 8,275,624, September 2012 is an electronic speech aid with primary focus on hypokinetic dysarthria, a speech disorder associated with Parkinson's disease.

In sum, many products exist that provide speech aid to the impaired user but are offered in several different product purchases, not in one application, like the Reverse Hearing Aid. The Reverse Hearing Aid is a hands free device which combines portability, fidelity, noise reduction, efficient power source, low profile, wireless transmission, competitive price range and smart voice recording with focus on anyone challenged with difficulty projecting their voice at a high enough energy level for comprehension.

With the penetration of wireless communication systems networks for mobile-phones, IPhone, IPads, 2 way radios etc., and bluetooth pairing capabilities, verbal communication with other people is possible anytime, anywhere.

### BRIEF DESCRIPTION OF THE DRAWINGS

FIG. 1 shows a fragmentary elevation of a person wearing my improved throat microphone with 2 Transponders, and Bluetooth

FIG. 2 shows the earpiece inserted into the wearers

FIG. 3 is the full view of the improved throat microphone

FIG. 4 shows the blue tooth technology chip

FIG. 5 shows the left transponder

FIG. 6 shows the right transponder

FIG. 7 is a rear elevation of the throat mic being worn by a person

FIG. 8 shows the 3.5 mm insertion connector

FIG. 9 is the full view of the front elevation of the throat mic being worn by a person with the connector inserted

FIG. 10 shows the side elevation of a person wearing the throat microphone with the connector inserted

FIG. 11 Shows the front view of the throat mic connected to a celluar device, I.,e. Cellphone

FIG. 12 shows the cell phone connected

FIG. 13 shows the splitter which provides the option for PPT or Vox options

FIG. 14 shows the full view rear elevation of a person wearing the throat mic connected to a cell phone

FIG. 15 shows the full view front elevation of a person wearing the throat mic connect to a cell phone

FIG. 16 shows the full view side elevation of a person wearing the throat mic connected to the cell phone

FIG. 17 shows the full perspective of a person wearing the throat mic connected to a 2 way radio.

FIG. 18 Shows the rear elevation of a person wearing the throat mic connected to the 2 way radio

FIG. 19 shows the rear elevation of the 2 way radio's belt clip for attaching to the persons clothing

FIG. 20 shows the full view front elevation of the 2 way radio connected with a 3.5 mm to the 2 way

FIG. 21 shows the front view of the 2 way radio

FIG. 22 shows the side elevation of the 2 way radio attached to the throat mic

FIG. 23 shows the different functions of the Reverse Hearing Aid and what that it is comprised of a microphone, transmitter, receiver, storage unit, signal processor, and speaker. The microphone used is a laryngophone, commonly known as a throat mic.

FIG. 24 shows the information signal flow diagram of the Reverse Hearing Aid whereby the output of the microphone will be an analog signal which will then be converted to a digital signal with audio codec. For the wireless transmission of the voice, the Pure Path Wireless Audio link will be used. This device transmits digital data from one point to another allowing fast data transfer and high quality audio streaming. The audio codec is compatible with the Pure Path. The receiver will also be a wireless audio link for the purpose of paring the transmission with the receiver. The microprocessor will be used to take the received digital voice and write it to a SD card for storage. The voice can then be outputted to a speaker for direct voice amplification

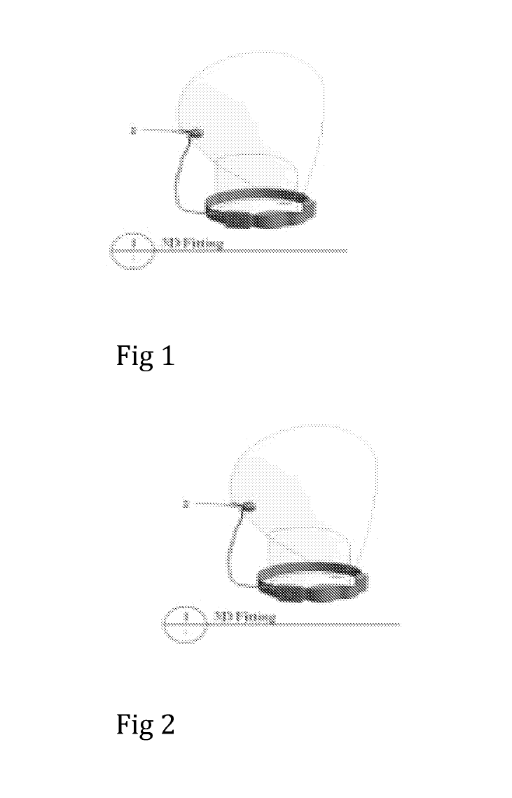

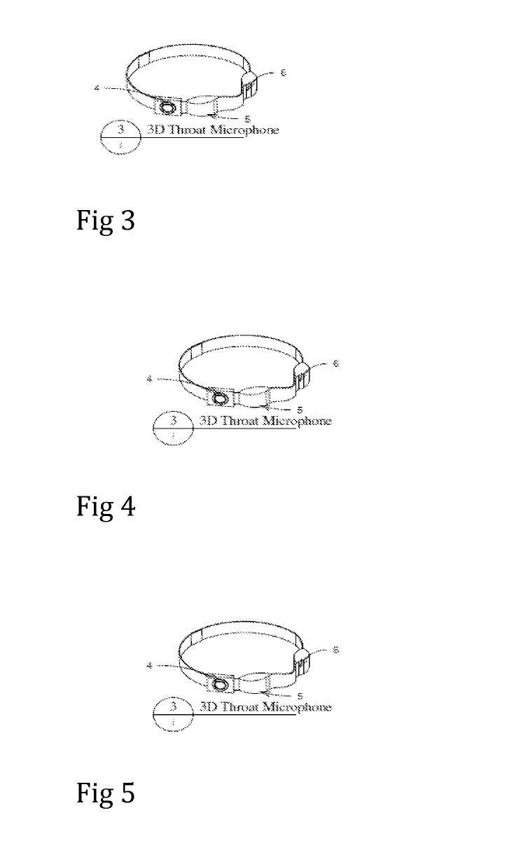

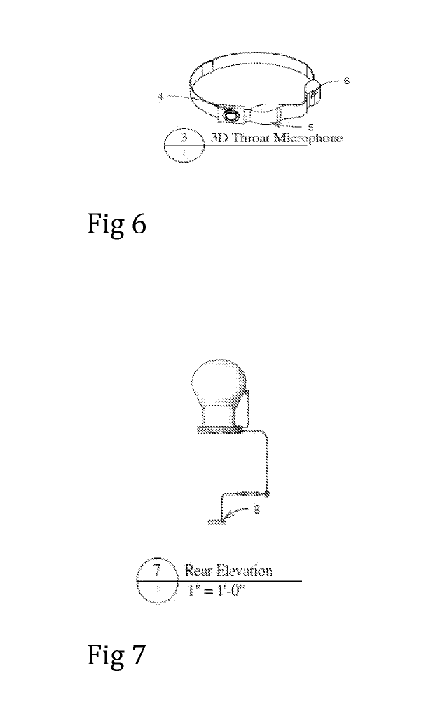

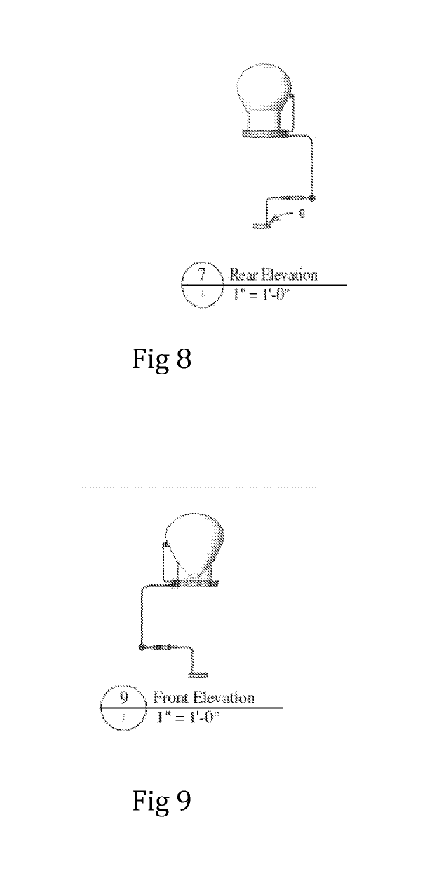

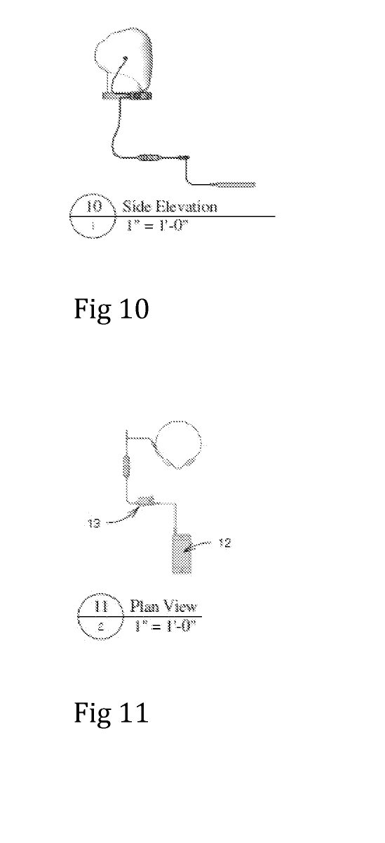

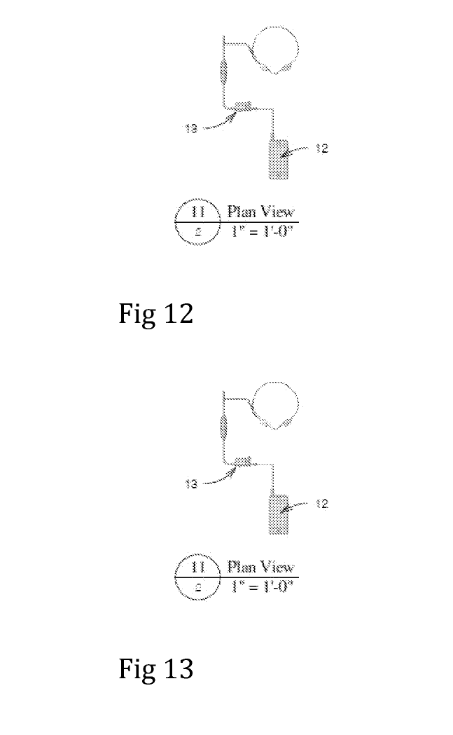

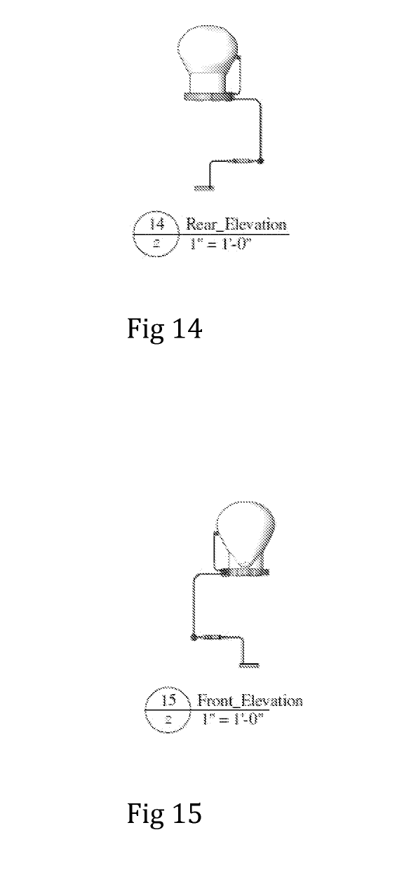

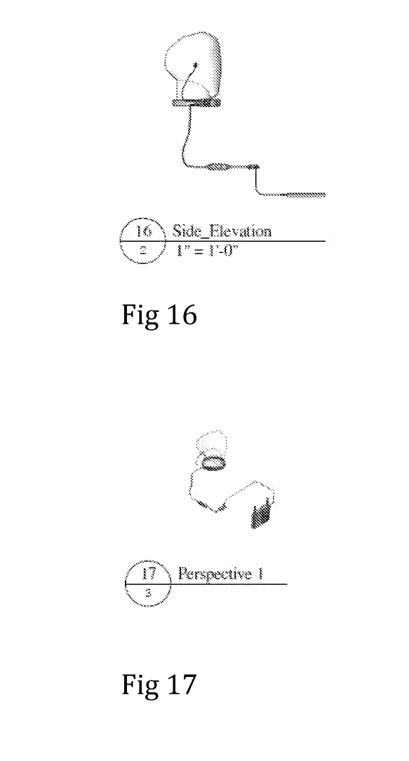

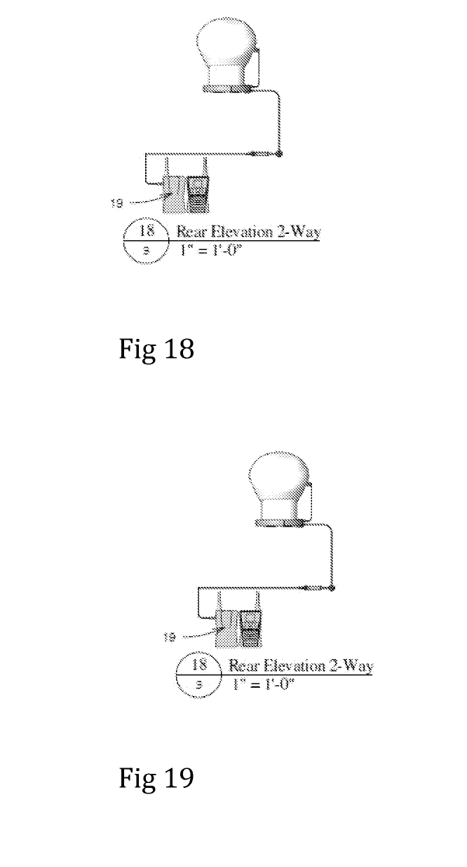

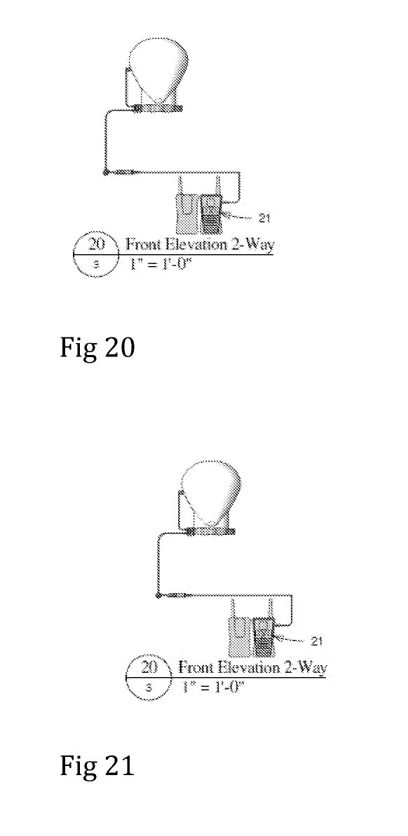

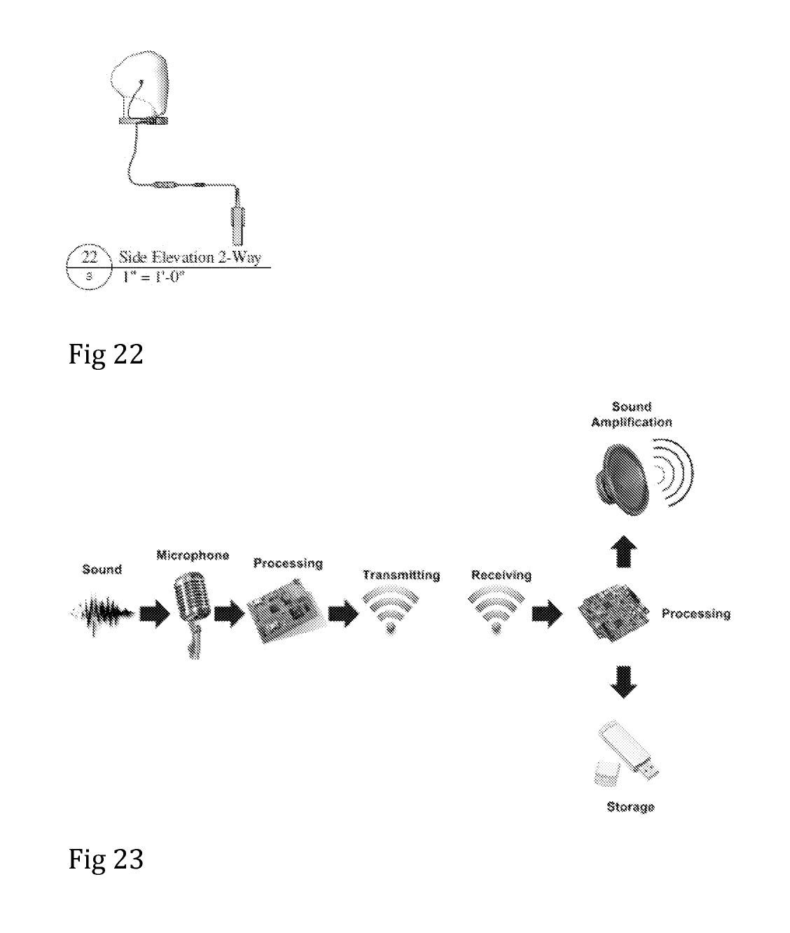

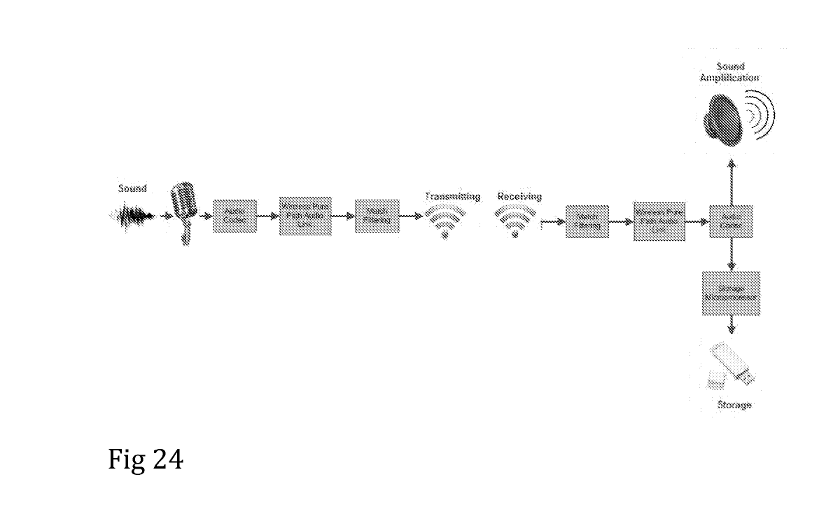

### DETAILED DESCRIPTION OF THE INVENTION

The present invention and new method of use meets the need to provide electronic speech aid to anyone challenged with the inability to speak loud enough to be heard. This is done by providing a solution with a new method and apparatus for use of a portable and wearable device, such as the throat microphone, which cancels out all outside noise through sensors that only pick up the skin vibration signals from the vocal cord when the user is talking, even if the user is speaking at a whisper.

Additionally, this new method and apparatus invention incorporates the use of the throat microphone with:
A. Everyday wireless communications technology, i.e., cellphone, IPhone, IPad, etc., and Bluetooth technology,
B. 2 way radio with or without Bluetooth
C. The portable affordable compact new product Reverse Hearing Aid

Statists show that more than 89 percent of the U.S. population has mobile broadband; and worldwide, there are more than 6 billion people with mobile phone subscriptions. Utilizing wireless communications as a tool for speech aid, allows any person with a comparable wireless communications device the ability to utilize that device as a speech aid if there is a need.

A. Detailed Description Utilizing the Throat Microphone and Wireless Communications, CellPhone, IPhone

Attaching the Bluetooth compatible throat microphone to a cellular phone device supports the new method of use of portable devices owned by millions. The Bluetooth compatible [or not] throat microphone has two sensors and is better for reproducing voice sounds corresponding to an amplified form of the electrical signals generated by the throat microphone.

Attaching the Bluetooth throat microphone to a wireless communications device, [IPhone, IPad, etc.,] allows the device to be used by the millions of people challenged with difficulty projecting their voice at a high enough energy level for comprehension.

The improved throat microphone, with or without the Bluetooth technology option allows the user the option of communications through IPhone, IPad etc. The user can elect to convert speech to text through voice messaging. The user will simply speak into the device, [rather than type], and the users words and phrases in spoken language will be converted to a machine-readable format for verification of spoken requests.

This will allow any audience, family members, Physicians, medical staff as well as the user to document or track a request. Data can be permanently stored in the wireless device, i.e., under messaging.

B. Detailed Description Utilizing the Throat Microphone and 2 Way Radio Communications

Attaching the Bluetooth compatible [or not] throat microphone to a 2 way radio supports the need to have an affordable portable device, and the new method of use for an existing device. The 2 way radio device is comprised of a built in microphone, transmitter, receiver, storage unit, signal processor, and speaker. The throat microphone is attached because it does not require the user to project his/her voice through the air, and it converts the energy from the sound waves produced by the individual to an electric signal.

The signal is transmitted wirelessly to the nearby station, and the signal is amplified to ultimately enable the communication between the individual and the intended audience at the other end of the radio.

The device is portable, has efficient power source, [as it can be battery operated], low profile, wireless transmission, and competitively priced. The device has the ability to transmit and receive, and provides the option of push to talk PPT, or hands free with the VOX option.

In addition, the radio can be clipped to the users clothing, and worn on the inside or outside or simply placed on a night stand, or bedside, or to the wheel chair etc., depending on the situation.

This new method meets the need for speech impaired individuals, by capturing low energy sound waves and transmitting wirelessly to be reproduced from a speaker.

C. Detailed Description Utilizing the Throat Microphone and the Reverse Hearing Aid-Portable/Affordable Device

Finally, a new method and apparatus and creative improvement of multiple devices used for speech aid for treating speech disorders, which combines these segmented features, purchased separately, into one product purchase.

This new method and improvement combines portability, fidelity, noise reduction, efficient power source, low profile, wireless transmission, smart voice recording device and competitive price range for anyone [not just Parkinson's Patients] with low tone voice in need of a speech aid. The invention will utilize the throat microphone [or any microphone] that receives low tone voice from a speech impaired user, filtering out noise and distortion, while transmitting wirelessly to an independent speaker and recording audio digitally. In addition, the stand alone device can be placed on a night stand, or bedside, or carried by the user or attached to the wheel chair etc., depending on the situation.

Unlike other Electronic Speech Aid which targets a specific disease, The Reverse Hearing Aid [RHA] captures the “True Voice”, of the person, and lets them be heard. It does not rely on voice prosthesis or use esophageal speech.

One important aspect is that The Reverse Hearing Aid uses the throat microphone which converts the energy from the sound waves produced by the individual to an electric signal. As part of the design, the signal is transmitted wirelessly to a nearby station prior to storage. At the station, the signal will be sampled and stored internally with external storage capabilities. The signal is amplified to ultimately enable the communication between the individual and the intended audience.

Most importantly The Reverse Hearing Aid allows the medically challenged voice person the ability to be heard and to communicate their needs, and it introduces the pairing of the Bluetooth device on a wireless device cell phone, I/Phone or IPad to allow for talk to text along with limited recording and storage.

This free-standing device, offers a hands free option or not, for smart voice recording and high capacity digital storage for preservation of recordings of short statements or requests, which captures and stores the users immediate demands, or final last words of “goodbye” from a dying loved one, or final will and testament.

Further, the device has optional fingertip [PPT] push-to-talk functionality, or VOX option which allows the user to answer and end calls.

This new method meets the need for speech impaired individuals, by capturing low energy sound waves and transmitting wirelessly to be reproduced from a speaker and stored for future use.

Those precious last words can now be heard, by the loved one and captured by recording or text for long-lasting memories for years to come.

It is understood that the description herein is intended to be illustrative and not restrictive. Many embodiments as well as many applications besides the examples provided will be apparent to those of skill in the art upon reading the above description. The scope of the invention should, therefore, be determined not with reference to the above description, but should instead be determined with reference to the appended claims, along with the full scope of equivalents to which such claims are entitled. The omission in the following claims of any aspect of subject matter that is disclosed herein is not a disclaimer of such subject matter, nor should it be regarded that the inventor did not consider such subject matter to be part of her disclosed inventive subject matter.

What is claimed:

1. An improved method of use and apparatus for a Throat microphone specifically targeted to speech disorders associated with the millions of people challenged with having difficulty projecting their voice at a high enough energy level for comprehension. The improved device is a throat microphone which has two sensors. The additional improved method of use for this device, as a speech aid is the pairing of a cellular phone or wireless communications device, i.e., IPhone, IPad, etc., with [or without]Bluetooth technology using a 3.5 mm connector.

2. An improved method and apparatus using the Throat Microphone and a 2 way radio [with a 3.5 mm connector], specifically targeted for use for speech disorders associated with the millions of people challenged with having difficulty projecting their voice at a high enough energy level for comprehension. The user is able to both transmit and receive with the device and have a conversation with anyone within a 15 mile radius or further as long as they are on the same radio frequency.

3. The speech aid of claim 1, wherein the said microphone is a Throat Microphone, lapel microphone, or any selected group of microphones consisting of microphones that work from within larger pieces of technology to free-standing devices, with or without Bluetooth.

4. The speech aid of claim 2, wherein the said microphone is a Throat Microphone, lapel microphone or any selected group of microphones consisting of microphones that work from within larger pieces of technology to free-standing devices, with or without Bluetooth

5. An improved electronic speech aid device and method of use and apparatus improvement which combines multiple speech aid products to provide portability, fidelity, noise reduction, efficient power source, low profile, wireless transmission, smart voice recording device and competitive price range for anyone with low tone voice in need of a speech aid. The improved device utilizes the throat microphone [or any microphone] that receives low tone voice from a speech impaired user, filtering out noise and distortion, while transmitting wirelessly to an independent speaker and recording audio digitally.
